(19) United States
(12) Patent Application Publication
(10) Pub. No.: US 2023/0274043 A1
(43) Pub. Date: Aug. 31, 2023

(54) SYSTEM AND METHOD FOR MODELING FACILITIES INFRASTRUCTURE

(71) Applicant: AT&T Intellectual Property I, L.P., Atlanta, GA (US)

(72) Inventors: Jianxiong Dong, Pleasanton, CA (US); Eric Zavesky, Austin, TX (US); David Crawford Gibbon, Lincroft, NJ (US); Louis Alexander, Franklin, NJ (US)

(73) Assignee: AT&T Intellectual Property I, L.P., Atlanta, GA (US)

(21) Appl. No.: 17/681,080

(22) Filed: Feb. 25, 2022

(51) Int. Cl. G06F 30/13; G06T 11/00

(52) U.S. Cl. CPC G06F 30/13; G06T 11/00; G06T 2200/24; G06F 2111/18

(57) ABSTRACT

Aspects of the subject disclosure may include, for example, a device with a processing system including a processor; and a memory that stores executable instructions that, when executed by the processing system, facilitate performance of operations of ingesting facilities infrastructure data for more than one facility; training a machine-learning (ML) model from the facilities infrastructure data, wherein the ML model infers features absent in the facilities infrastructure data and yields a score of a facility described by the facilities infrastructure data; receiving a query for a region from a user; identifying one or more facilities provided in the region; generating a map of the one or more facilities using the ML model; and providing a visualization interface to the user including the map and the score of the one or more facilities responsive to the query. Other embodiments are disclosed.

### FIELD OF THE DISCLOSURE

The subject disclosure relates to a system and method for modeling facilities infrastructure.

### BACKGROUND

Locational information about facilities infrastructure is either non-existent, outdated, or unreliable. Traditionally, call before you dig (CBYD) programs require an on-site survey due to the unreliable nature of existing facilities infrastructure information.

### BRIEF DESCRIPTION OF THE DRAWINGS

Reference will now be made to the accompanying drawings, which are not necessarily drawn to scale, and wherein:

FIG. 1 is a block diagram illustrating an exemplary, non-limiting embodiment of a communications network in accordance with various aspects described herein.

FIG. 2A is a map illustrating problems in facilities infrastructure data.

FIG. 2B is a block flow diagram illustrating an example, non-limiting embodiment of a system within the communication network of FIG. 1 performing processes in accordance with various aspects described herein.

FIG. 3 is a block diagram illustrating an example, non-limiting embodiment of a virtualized communication network in accordance with various aspects described herein.

FIG. 4 is a block diagram of an example, non-limiting embodiment of a computing environment in accordance with various aspects described herein.

FIG. 5 is a block diagram of an example, non-limiting embodiment of a mobile network platform in accordance with various aspects described herein.

FIG. 6 is a block diagram of an example, non-limiting embodiment of a communication device in accordance with various aspects described herein.

### DETAILED DESCRIPTION

The subject disclosure describes, among other things, illustrative embodiments for generating accurate data modeling facilities infrastructures. Other embodiments are described in the subject disclosure.

One or more aspects of the subject disclosure include a device with a processing system including a processor; and a memory that stores executable instructions that, when executed by the processing system, facilitate performance of operations of ingesting facilities infrastructure data for more than one facility; training a machine-learning (ML) model from the facilities infrastructure data, wherein the ML model infers features absent in the facilities infrastructure data and yields a score of a facility described by the facilities infrastructure data; receiving a query for a region from a user; identifying one or more facilities provided in the region; generating a map of the one or more facilities using the ML model; and providing a visualization interface to the user including the map and the score of the one or more facilities responsive to the query.

One or more aspects of the subject disclosure include a non-transitory, machine-readable medium, with executable instructions that, when executed by a processing system including a processor, facilitate performance of operations including receiving facilities infrastructure data for more than one facility; training a machine-learning (ML) model from the facilities infrastructure data, wherein the ML model infers features absent in the facilities infrastructure data and yields a score of a facility described by the facilities infrastructure data; receiving a query for a region from a user; identifying one or more facilities provided in the region; generating a map of the one or more facilities using the ML model; and providing a visualization interface to the user including the map and the score of the one or more facilities responsive to the query.

One or more aspects of the subject disclosure include a method of creating, by a processing system including a processor, a machine-learning (ML) model from facilities infrastructure data, wherein the ML model infers features absent in the facilities infrastructure data and yields a score of a facility described by the facilities infrastructure data; receiving, by the processing system, a query for a region from a user; identifying, by the processing system, one or more facilities provided in the region; generating, by the processing system, a map of the one or more facilities using the ML model; and providing, by the processing system, a visualization interface to the user including the map and the score of the one or more facilities responsive to the query.

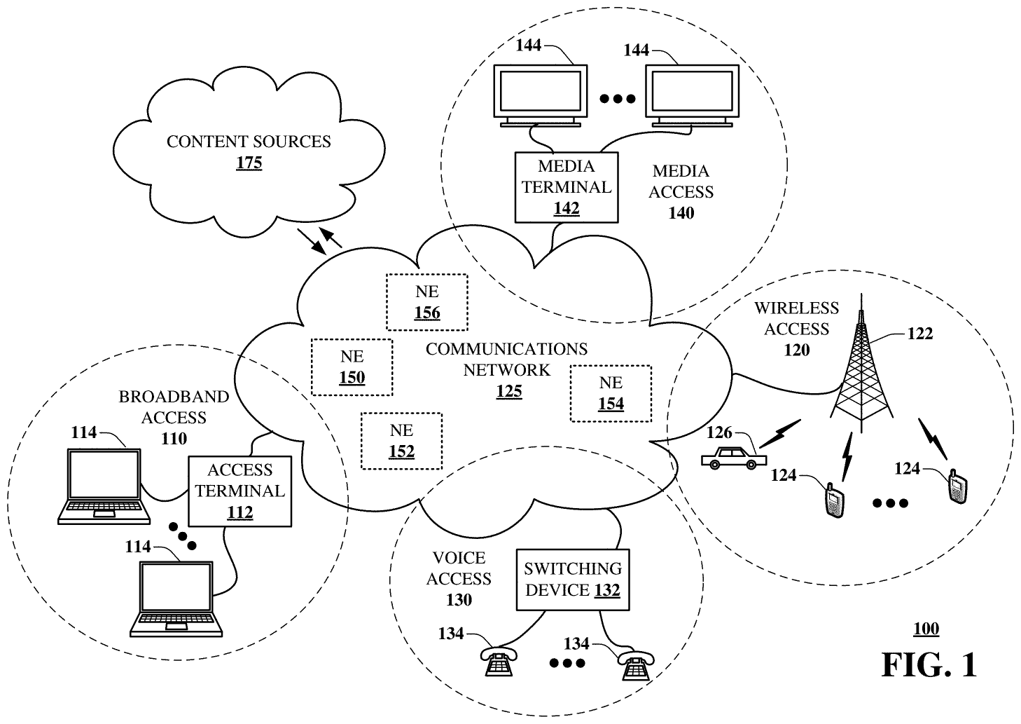

Referring now to FIG. 1, a block diagram is shown illustrating an example, non-limiting embodiment of a system 100 in accordance with various aspects described herein. For example, system 100 can facilitate in whole or in part ingesting facilities infrastructure data; training a machine-learning (ML) model from the facilities infrastructure data; identifying one or more facilities provided in a region specified in a user query; generating a map of the one or more facilities using the ML model; and providing a visualization interface including the map and the score of the one or more facilities responsive to the query. In particular, a communications network 125 is presented for providing broadband access 110 to a plurality of data terminals 114 via access terminal 112, wireless access 120 to a plurality of mobile devices 124 and a vehicle 126 via base station or access point 122, voice access 130 to a plurality of telephony devices 134, via switching device 132 and/or media access 140 to a plurality of audio/video display devices 144 via media terminal 142. In addition, communication network 125 is coupled to one or more content sources 175 of audio, video, graphics, text and/or other media. While broadband access 110, wireless access 120, voice access 130 and media access 140 are shown separately, one or more of these forms of access can be combined to provide multiple access services to a single client device (e.g., mobile devices 124 can receive media content via media terminal 142, data terminal 114 can be provided voice access via switching device 132, and so on).

The communications network 125 includes a plurality of network elements (NE) 150, 152, 154, 156, etc. for facilitating the broadband access 110, wireless access 120, voice access 130, media access 140 and/or the distribution of content from content sources 175. The communications network 125 can include a circuit switched or packet switched network, a voice over Internet protocol (VoIP) network, Internet protocol (IP) network, a cable network, a passive or active optical network, a 4G, 5G, or higher generation wireless access network, WIMAX network, UltraWideband network, personal area network or other wireless access network, a broadcast satellite network and/or some other communications network.

In various embodiments, the access terminal 112 can include a digital subscriber line access multiplexer (DSLAM), cable modem termination system (CMTS), optical line terminal (OLT) and/or other access terminal. The data terminals 114 can include personal computers, laptop computers, netbook computers, tablets or other computing devices along with digital subscriber line (DSL) modems, data over coax service interface specification (DOCSIS) modems or other cable modems, a wireless modem such as a 4G, 5G, or higher generation modem, an optical modem and/or other access devices.

In various embodiments, the base station or access point 122 can include a 4G, 5G, or higher generation base station, an access point that operates via an 802.11 standard such as 802.11n, 802.11ac or other wireless access terminal. The mobile devices 124 can include mobile phones, e-readers, tablets, phablets, wireless modems, and/or other mobile computing devices.

In various embodiments, the switching device 132 can include a private branch exchange or central office switch, a media services gateway, VoIP gateway or other gateway device and/or other switching device. The telephony devices 134 can include traditional telephones (with or without a terminal adapter), VoIP telephones and/or other telephony devices.

In various embodiments, the media terminal 142 can include a cable head-end or other TV head-end, a satellite receiver, gateway or other media terminal 142. The display devices 144 can include televisions with or without a set top box, personal computers and/or other display devices.

In various embodiments, the content sources 175 include broadcast television and radio sources, video on demand platforms and streaming video and audio services platforms, one or more content data networks, data servers, web servers and other content servers, and/or other sources of media.

In various embodiments, the communications network 125 can include wired, optical and/or wireless links and the network elements 150, 152, 154, 156, etc. can include service switching points, signal transfer points, service control points, network gateways, media distribution hubs, servers, firewalls, routers, edge devices, switches and other network nodes for routing and controlling communications traffic over wired, optical and wireless links as part of the Internet and other public networks as well as one or more private networks, for managing subscriber access, for billing and network management and for supporting other network functions.

Facilities (e.g., electrical, telecom, wireless, water, etc.) infrastructure data may be lacking in several respects. First, multiple entities or sources of facilities infrastructure data, e.g., facilities owners or operators, are reluctant to share data. Furthermore, the consistency of that data presents a challenge when merging facilities data for different facilities or from various locations. With large enterprises, rich coverage of a facility database (e.g., knowing all facility locations, types, and connectivity) may be challenging.

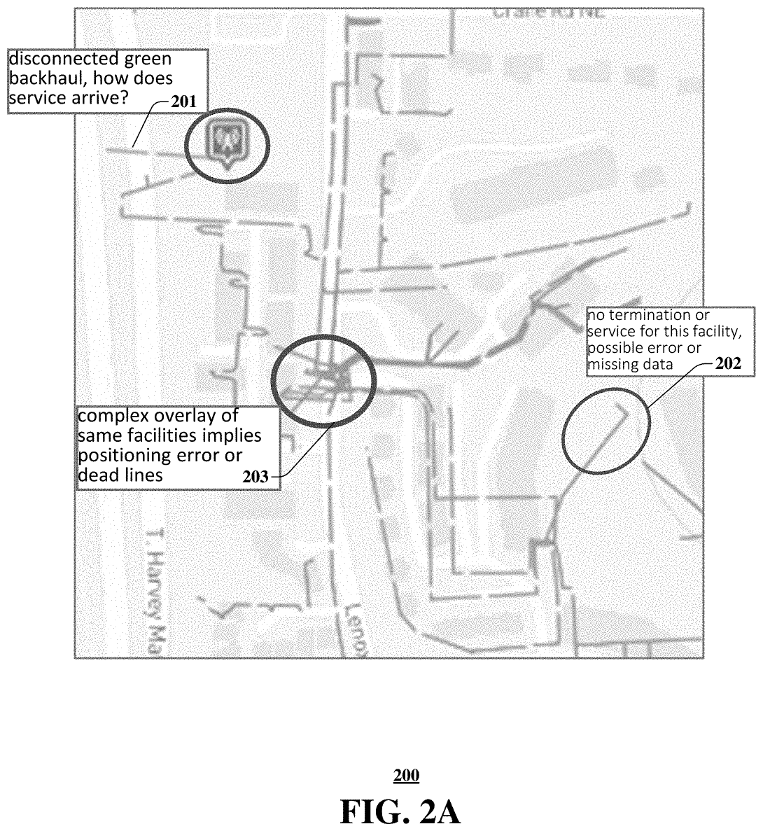

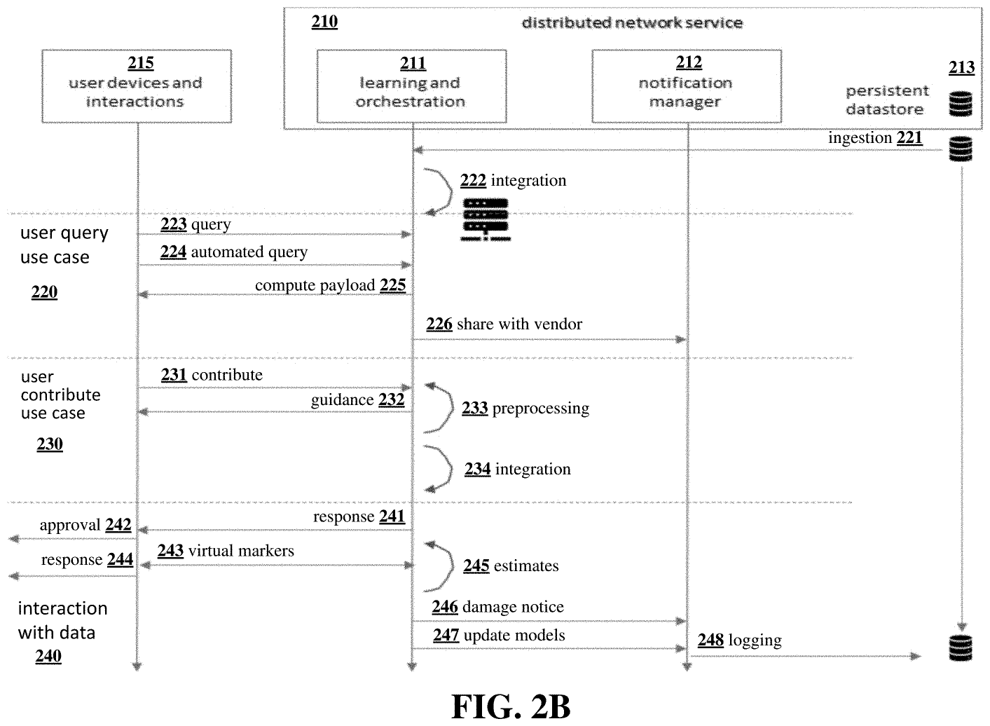

FIG. 2A is a map 200 illustrating problems in facilities infrastructure data. As shown in FIG. 2A, at 201, map 200 illustrates a disconnected backhaul for a wireless service. At 202, map 200 illustrates missing data in the form of a termination for the facility. Big data methods and machine learning analytics may help to “self-heal” gaps in facilities infrastructure data by providing contextual imputation. For example, if a service exists at two points, a facility must connect them. At 203, map 200 illustrates a complex overlay of facilities. Hashing partial data sources from other entities (e.g., indexing parcels/domiciles and civil roads to find nearest facilities) may also help to cure gaps in the data. Both of these methods enable and incentivize guarded sharing of entities using partial data layers between enterprises (allow ‘blacked out’ regions without specific knowledge of what is there) to improve overall consistency of the database. Data consistency refers to data that is constant over time or some other relationship. For example, a single reference to the same facility, though names may vary (record linkage), and multiple providers may describe the same set of entities by different, but consistent reference by each provider (e.g., specific codes by location Pennsylvania-1600-1, by internal company index Cable #8675309, or other notation that can be subsequently cross-referenced). This data ambiguity is automatically resolved, and individual company data relationships can be maintained.

Second, the accuracy of facilities infrastructure data is often lacking with regard to the shape and positioning of facilities and infrastructure locations (e.g., underground, changes brought about by a home renovation, line-of-sight challenges, etc.). The facilities owner or operator is often solely responsible for improving such data, but user contributions (human or automated) of new data can be safely incorporated with direct mapping, pictures, etc. or system-specified anchoring features for visual odometry (e.g., user-powered surveying). By democratizing the data, users may contribute modifications when renovating property or moving items (e.g., a mailbox) on their property. Additionally, automated tools can provide an accurate shape (e.g., support 3D view (depth)) as well (e.g., digging that has lidar+heat map+electromagnetic detection of lines) to improve the quality of the database and representations of the facilities infrastructure.

Finally, current facilities infrastructure databases (also referred to as “layers”) are not prepared for a rich blend of physical and virtual artifacts (known as the “metaverse,” a form of augmented reality (AR)). While the metaverse is currently utilized for entertainment needs, a connected facilities database would contribute virtual objects to facilitate both back-end computations as well as execution of front-end user applications. For example, virtual representations (e.g., glowing warning signs, guidance arrows, etc.) may include multiple layers/heat maps for facilities. Also, representation in the metaverse allows these items to directly collect interaction data from the user and contribute it back to the database. For example, a user unearthed a “virtual” buried cable or water main, but found no object, so the primary database may receive unsolicited updates from the user.

FIG. 2B is a block flow diagram illustrating an example, non-limiting embodiment of a system within the communication network of FIG. 1 performing processes in accordance with various aspects described herein. As shown in FIG. 2B, system 210 is a distributed network service comprising a learning and orchestration module 211 and a notification manager 212, collectively referred to as modules. Such modules may be implemented in cloud-based network elements, such as network elements 150, 152, 154 and 156 illustrated in FIG. 1.

Learning and orchestration module 211 provides standard components of a machine learning (ML) model where inputs are facilities and infrastructure data that describes the facilities and outputs are related facts or computed scores about facilities known to the distributed network service. In an embodiment, the learning and orchestration module 211 is trained to capture and respond with one or more facts about spatial objects, presented in materials such as textual, geographic or visual information. In one example, this ML model may use a graph-based representation, such as GraphQL (an open-source data query and manipulation language for application program interfaces (APIs), and a runtime for fulfilling queries with existing data) to attribute facts to singular facilities: installation date, service date, type of entity, capacity of entity, location of entity, etc. Inherent to the GraphQL language, facility infrastructure data may also include both hierarchical relationships (entity 1 is a hub that connects facilities a, b, c) and functional relationships (when enabled, facility 1 will activate facility 2 and facility 3 in series). This embodiment allows new infrastructure data to be created, inferred, modified, and destroyed and for this representation to receive complex queries (which facility has any impact on facility Q) and evaluate the impact complex actions (determine the “reliability” and “fitness” of facilities in an adjacent area after disabled all facilities with capability X within a radius of Y feet of location Z). In an embodiment, additional textual, geographic and visual information may aid the ML model to “fill in the gaps” presented by the facilities infrastructure data. In another embodiment, graphical neural networks may be utilized to incorporate the various features of a facility with those that are connected to it (either by physical proximity or other connectivity for delivery of a service); where the graphical neural network may serve both as a learned model and as a database for probabilistic query responses. In still another embodiment, the learning and orchestration ML model is as a hybrid database and classification model. In one example, the facilities and infrastructure data described above are stored in a database. In the same example, one or more machine learning classification (or regression) models may be trained to provide discrete outputs (or continuous scores) according to certain input criterion. In a related example, one classification may provide a “reliability” or “fitness” score for one or more facilities. Here, the input to the learning and orchestration module may first be a query related to disabling all facilities with capability X within a radius of Y feet of location Z. These inputs would be used to retrieve all relevant rows from the database and the individual infrastructure data (columns) of those rows may be encoded as individual input vectors to the machine learning model. The model may provide one or more scores that determine the impacts on facilities included as inputs based on spatial and attribute relationships learned during the creation of the model. In a related embodiment, classifier models such as gradient boosted trees (GBT) or random forests (RF) may be utilized to correlate the features (both numerical and categorical in nature) and the discrete labels (e.g., a binary failure or non-failure indicator) or continuous labels (e.g., the fitness, health, quality, or other reliability metric) inferred by a probabilistic prediction or regression (in the case of a continuous label space).

In another embodiment models with specific time-sensitivity to the change of features like ARIMA (Autoregressive integrated moving average), LSTMs (Long short-term memories), or transformer models may be utilized to better account for both short- and long-term cyclical behaviors of model features. Specifically, LSTMs and transformer models are deep neural network variants that not only create their own feature space (derived from repeated exposure to new samples), but also learn to how to weight recursive model topologies that are intrinsic in the models' hierarchical composition. In all of the above embodiments, the learning and orchestration module 211 accommodates functions for integration of new data, sharing of factual infrastructure data as the result of query, and the computation of one or more scores related to the facilities and facts stored within the distribute network service.

Notification manager 212 provides an alerting interface, generates messages triggered by events with specific occurrences and delivery methods controlled by system governance. System 210 also includes persistent memory storage, hereinafter referred to as database 213, that can store and retrieve information for presentation to a user. System 210 may also use one or more user devices 215, such as smartphone apps and other electronic interface devices to communicate with the user. System 210 can acquire information about facilities infrastructure through a network from various sources such as external systems, both publicly available on the Internet, and through private information storage of entities associated with the facilities infrastructure.

Method 220 is a user query use case that begins in step 221 where learning and orchestration module 211 ingests an overlay of facilities infrastructure data from various sources, such as facilities owners, operators, or publicly available information, including government sources. Such facilities infrastructure data comprises several types of facilities data, such as power distribution, telecom, cellular, cable, water, sewer, etc. and the location of the infrastructure thereof. The facilities infrastructure data includes the location of facilities (e.g., a map identifying where each buried line, cable, etc. runs from a central location to a distribution hub providing the services to a premises), a quality of the services provided (e.g., the capacity and speed provided by the service), an extent of service interruptions when the facilities are damaged, repair costs and outage lengths, etc. In one embodiment, the system ingests existing infrastructure installation data that indicate the time of installation, last service, material type and location. In another embodiment, service level data (e.g., throughput of data on a telecommunications line, throughput of water or gas on a hard facility pipe, or number of errors on any of these facilities) may be added via automated systems or from home-adjacent inspection and metering tools (e.g., meters, residential gateways, self-reporting mobile applications, etc.). In yet another embodiment, the system ingests third-party data that has been constructed via automatic means or via external observations and aggregations, such as specification and placement information via geolocation tables (e.g., location-attributed rows), via ad-hoc or intermitted updates. Learning and orchestration module 211 stores the facilities infrastructure data in database 213.

Next in step 222, system 210 integrates and normalizes the data stored in database 213. System 210 detect gaps in coverage by expected density or measured network traffic in a region. System 210 validates connectivity between one or more points. Optionally, system 210 explicitly solicits user contributions which may serve as a core driver for subsequent operation. A core driver for system 210 may include a single query (e.g., attributes about the facilities in this area), a complex query (e.g., compute affected facilities in both the user's ownership as well as those in the ownership of others in the area), or a prediction or estimate for a particular action (e.g., compute the staging order and impact of an action in this area). All of these core drivers may be the initial conditions that create responses and subsequent interactions as denoted by use case methods 220, 230 and 240.

Then in step 223, system 210 receives a query from a user that either requests an identification of facilities in a particular region or prepares the database to receive an unsolicited data update. Specifically, a user can query facility info based on parcel or address information. Or a user can contribute data so that database 213 can be updated in step 222. Data update examples are provided in step 224 below.

In step 224, an automated query can specify an explicit parcel, or global positioning system (GPS) coordinates to identify an area, and system 210 can resolve the specifications against facts or attributes known about facilities in the area. Other examples of facts and attributes may include user account information or facility attributes such as locations, geometry (i.e., shape), facility types (copper or fiber), or active account numbers or building. In an embodiment, a user may provide a visual example for location, such a photo, which system 210 can recognize to identify the area. In an embodiment, a user can provide a desired action (e.g., a need to dig, where is it safe to make a trench, etc.). In another embodiment, the “user” can be an automated entity (e.g., automated backhoe, digging, trench, pole installer). As another example, a facility employee can request results that detail intermittent steps required for operational (enabling a specific facility) or job (installing a facility, testing that facility, enabling the facility) completion.

In step 225, system 210 creates a map in response to the query that delineates the facilities infrastructure on the map. In one example, this map contains geometric objects for facilities (e.g., GeoJSON, a JavaScript object notation (JSON) based format designed to represent the geographical features with their non-spatial attributes, for example, in two dimensions including location and shape). In another example, structural descriptions of facilities (e.g., computer aided design (CAD) based dimensional descriptions and positioning information for each facility) can used for real-world physical alignment of a map and a facility. Facilities attributes can also be returned such as the facility age, building and cable type (e.g., copper or fiber), which may be conveyed both in their native semantic or numeric form or with generated “quality” or “fitness” scores to be mapped to heatmaps or visualization aides.

In step 226, the response can provide a visualization interface such as an augmented reality (AR), a two-dimensional map overlay, a three-dimensional line of sight conflict from user location, or a navigation path that avoids the facilities that is shared with a vendor through notification manager 212.

Method 230 is a use case of a user providing information to update system 210. Method 230 begins in step 231, where a user contributes additional data for refinement of facilities infrastructure data. In an embodiment, a user may contribute an explicit image, audio, or electromagnetic survey sample from a user device or an automated system. The user device may also supply other sources of information, like audio echo location, volumetric video, or three-dimensional laser scanning (e.g., light detection and ranging, or “lidar”). In an embodiment, a user may simply send a new data capture to system 210 to “figure out” whether an update should apply to facilities infrastructure data from, for example, a new construction or renovation.

In step 232, system 210 may optionally provide feedback such as anchors or examples (e.g., turn left, right, bend down for line-of-sight capture) that help improve a spatial consistency of the user contribution. System 210 may trigger active signals (e.g., electromagnetic ping, sound, etc.) to help user navigate to specific capture or feedback assistance.

In step 233, system 210 may preprocess user contributed data to assess quality and send a response for an updated example.

In step 234, system 210 integrates new data from the user in various contexts into the facilities infrastructure model. In one embodiment, an explicit example from a photograph, a three-dimensional scan of an object, or a generic description (“pipe”) and sensor data (e.g., copper composite with conductance of 0.223 Siemens) may contribute to one or more facility classes. System 210 may recommend a guess from the context of a nearby facility (e.g., cable and telecommunications lines are located on common poles) so the replacement facility must be of a similar nature, where the user may provide additional subsequent details. System 210 may contextually estimate how a facility is planned (e.g., a neighborhood maybe designed to string straight lines from one section to another).

Method 240 is a use case relating to a user interacting with system 210. Method 240 begins in step 241, where a user receives a response from system 210. The response in step 241 may be as a result from an initial user query in step 223, a semi-automated query in step 224, or ongoing work or interactions with facility data in the area in the course of job responsibilities of the user (e.g., installation or replacement of a facility, not illustrated in FIG. 2B). Responses may include instructions for guided interactions such as autonomous marking of facilities with a shallow depth in the immediate location. Other responses may include computed quality and fitness scores, which may be provided for all facilities in the area, such that the user may select one or more to specifically take action upon.

Next in step 242, the system 210 seeks approval or confirmation for the one or more items to modify. In one embodiment, system 210 pre-approves a navigation app or autonomous marking or planning app that can ‘fast-track’ (or auto-approve by privilege of the user or an associated low-risk score) certain requests without human intervention. For example, a mailbox post may have been hit by a car and needs replacing. In this example, the system will auto-approve moving the mailbox post 2.5 feet to avoid removal of existing concrete from an original structure, which may have higher associated costs to the user. Auto-approval is possible because the system has good facility info near the mailbox post and the navigation-based app can guide a user to safely reallocate the mailbox post.

In step 243, system 210 may generate virtual markers for user interaction that updates a metaverse representation of the facility. Here, the metaverse provides users with virtual markers showing the exact facility location and geometric shape. The users can update the system to show how objects are installed. Some object information such as location and shape may be provided to the system. System 210 may associate a risk for potential damage of the primary facility or those in the area if the facility is in a particularly crowded (or sensitive) location. These additional risks may be visualized with the metaverse by a response that colors, notifies, or alerts the user or the user's tools automatically.

In step 244, system 210 provides an overlay in AR, a map, or via another guided system for user visualization to avoid damaging facilities infrastructure.

In step 245, system 210 estimates damages of facilities via interaction logging and validation of user actions against the initial data response in step 241 to the user and approval in step 242 by the user. For example, during user interaction, system 210 may log damage to a facility and notify the owner or nearby facilities.

In step 246, system 210 may create a notification that is sent both to the user and the facilities owner. In one example, the notification sent to the user may solicit additional information that describes a challenge or issue that caused this approved action in step 242 to fail unexpectedly. This challenge information related to the damage may be persisted in database 213 in hopes of preventing facilities damages later. For example, system 210 allows a user to interrupt their process if they discover a facility, e.g., while in the process of digging. In another embodiment, this notification may be utilized to attribute damage or impact to adjacent facilities. In another embodiment, this notification may be utilized by other owners to modify their use of facilities. For example, if a facility that wirelessly transmits data (e.g., an “edge” router) to surrounding customers is damaged and is now operating at reduced capacity, the owner may update their own usage of the facility and simultaneously mark the facility as damaged or functioning at reduced capacity within the database 213.

In step 247, system 210 updates facilities infrastructure models, and shares the updates with related parties via notification manager 212. In one embodiment, continuing from step 246, for a specific damage, the challenge information may also be used by the system to learn and update learning and orchestration module 211. In one example, these models may use the challenge information (e.g., difficulty due to density of facilities in the area) to identify future challenge scenarios based on similarity. In another example, the models may produce predictive scores or ratings for the facilities based on the historical frequency of a particular challenge (e.g., a specific query in step 223 and associated responses in steps 241, 244 with user and one or more user devices 215 always leads to high rates of damage). In other embodiments, such updates may include an update of the location of facilities, an update of a user profile (aggressiveness, contributions, tolerances), an update of related context (e.g., found power line near a cable line), or an update of owners to be notified for recent activity or metaverse object.

In step 248, all interactions (actions, marking, metaverse updates, logging, damages, and notifications) for a specific response in step 241 (or class of responses) are logged to persistent store. This store is retained as both an immutable persistent record of activities so that all owners of facilities data in the area achieve transparency for interactions as well as for future system interactions where the data is to be ingested again 221 for unplanned or additional leanings and interactions.

Compared to prior systems, the proposed method provides a system guided query and response notification system using learned relationships between facilities information from several facilities data types. The proposed system introduces novel response formats, including map, augmented reality, and location-anchored interactive response data. Novel equipment for pinpointing locations and configurations of facilities data and sensing facility performance data are distinctly accommodated as first-class contributors with the proposed system. The proposed system reduces the burden on both human and automated users while contributing new facilities data to the system. Finally, the proposed system provides a method for continuous identification and subsequent predictive scoring of facilities quality and failure conditions in response to modifications of related facilities (e.g., those discovered through a graph-based representation) such that preemptive repairs and updates may be coordinated without explicit planning and coordination between respective maintainers of the independent facility types.

While for purposes of simplicity of explanation, the respective processes are shown and described as a series of blocks in FIG. 2B, it is to be understood and appreciated that the claimed subject matter is not limited by the order of the blocks, as some blocks may occur in different orders and/or concurrently with other blocks from what is depicted and described herein. Moreover, not all illustrated blocks may be required to implement the methods described herein.

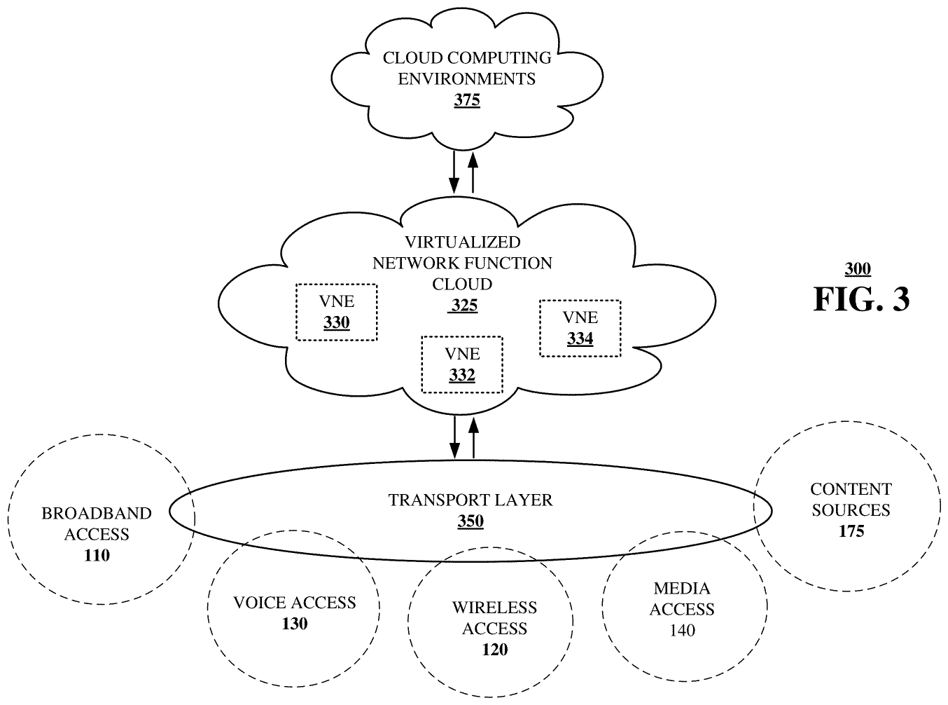

Referring now to FIG. 3, a block diagram is shown illustrating an example, non-limiting embodiment of a virtualized communication network 300 in accordance with various aspects described herein. In particular a virtualized communication network is presented that can be used to implement some or all of the subsystems and functions of system 100, the subsystems and functions of system 210, and methods 220, 230 and 240 presented in FIGS. 1, 2B and 3. For example, virtualized communication network 300 can facilitate in whole or in part ingesting facilities infrastructure data; training a machine-learning (ML) model from the facilities infrastructure data; identifying one or more facilities provided in a region specified in a user query; generating a map of the one or more facilities using the ML model; and providing a visualization interface including the map and the score of the one or more facilities responsive to the query.

In particular, a cloud networking architecture is shown that leverages cloud technologies and supports rapid innovation and scalability via a transport layer 350, a virtualized network function cloud 325 and/or one or more cloud computing environments 375. In various embodiments, this cloud networking architecture is an open architecture that leverages application programming interfaces (APIs); reduces complexity from services and operations; supports more nimble business models; and rapidly and seamlessly scales to meet evolving customer requirements including traffic growth, diversity of traffic types, and diversity of performance and reliability expectations.

In contrast to traditional network elements—which are typically integrated to perform a single function, the virtualized communication network employs virtual network elements (VNEs) 330, 332, 334, etc. that perform some or all of the functions of network elements 150, 152, 154, 156, etc. For example, the network architecture can provide a substrate of networking capability, often called Network Function Virtualization Infrastructure (NFVI) or simply infrastructure that is capable of being directed with software and Software Defined Networking (SDN) protocols to perform a broad variety of network functions and services. This infrastructure can include several types of substrates. The most typical type of substrate being servers that support Network Function Virtualization (NFV), followed by packet forwarding capabilities based on generic computing resources, with specialized network technologies brought to bear when general-purpose processors or general-purpose integrated circuit devices offered by merchants (referred to herein as merchant silicon) are not appropriate. In this case, communication services can be implemented as cloud-centric workloads.

As an example, a traditional network element 150 (shown in FIG. 1), such as an edge router can be implemented via a VNE 330 composed of NFV software modules, merchant silicon, and associated controllers. The software can be written so that increasing workload consumes incremental resources from a common resource pool, and moreover so that it is elastic: so, the resources are only consumed when needed. In a similar fashion, other network elements such as other routers, switches, edge caches, and middle boxes are instantiated from the common resource pool. Such sharing of infrastructure across a broad set of uses makes planning and growing infrastructure easier to manage.

In an embodiment, the transport layer 350 includes fiber, cable, wired and/or wireless transport elements, network elements and interfaces to provide broadband access 110, wireless access 120, voice access 130, media access 140 and/or access to content sources 175 for distribution of content to any or all of the access technologies. In particular, in some cases a network element needs to be positioned at a specific place, and this allows for less sharing of common infrastructure. Other times, the network elements have specific physical layer adapters that cannot be abstracted or virtualized and might require special DSP code and analog front ends (AFEs) that do not lend themselves to implementation as VNEs 330, 332 or 334. These network elements can be included in transport layer 350.

The virtualized network function cloud 325 interfaces with the transport layer 350 to provide the VNEs 330, 332, 334, etc. to provide specific NFVs. In particular, the virtualized network function cloud 325 leverages cloud operations, applications, and architectures to support networking workloads. The virtualized network elements 330, 332 and 334 can employ network function software that provides either a one-for-one mapping of traditional network element function or alternately some combination of network functions designed for cloud computing. For example, VNEs 330, 332 and 334 can include route reflectors, domain name system (DNS) servers, and dynamic host configuration protocol (DHCP) servers, system architecture evolution (SAE) and/or mobility management entity (MME) gateways, broadband network gateways, IP edge routers for IP-VPN, Ethernet and other services, load balancers, distributers and other network elements. Because these elements do not typically need to forward substantial amounts of traffic, their workload can be distributed across a number of servers—each of which adds a portion of the capability, and which creates an overall elastic function with higher availability than its former monolithic version. These virtual network elements 330, 332, 334, etc. can be instantiated and managed using an orchestration approach similar to those used in cloud compute services.

The cloud computing environments 375 can interface with the virtualized network function cloud 325 via APIs that expose functional capabilities of the VNEs 330, 332, 334, etc. to provide the flexible and expanded capabilities to the virtualized network function cloud 325. In particular, network workloads may have applications distributed across the virtualized network function cloud 325 and cloud computing environment 375 and in the commercial cloud or might simply orchestrate workloads supported entirely in NFV infrastructure from these third-party locations.

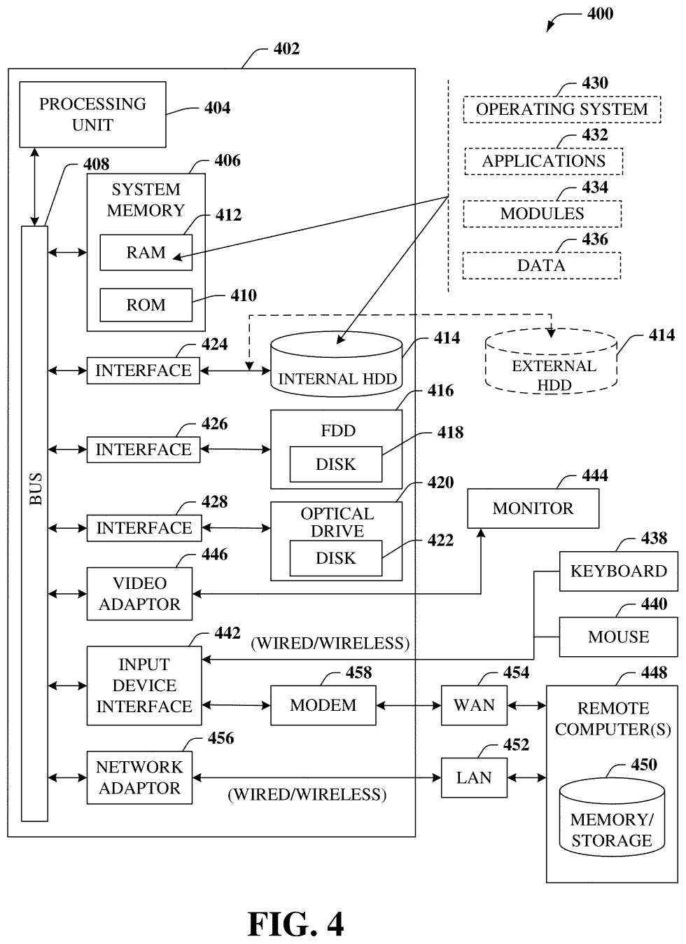

Turning now to FIG. 4, there is illustrated a block diagram of a computing environment in accordance with various aspects described herein. In order to provide additional context for various embodiments of the embodiments described herein, FIG. 4 and the following discussion are intended to provide a brief, general description of a suitable computing environment 400 in which the various embodiments of the subject disclosure can be implemented. In particular, computing environment 400 can be used in the implementation of network elements 150, 152, 154, 156, access terminal 112, base station or access point 122, switching device 132, media terminal 142, and/or VNEs 330, 332, 334, etc. Each of these devices can be implemented via computer-executable instructions that can run on one or more computers, and/or in combination with other program modules and/or as a combination of hardware and software. For example, computing environment 400 can facilitate in whole or in part ingesting facilities infrastructure data; training a machine-learning (ML) model from the facilities infrastructure data; identifying one or more facilities provided in a region specified in a user query; generating a map of the one or more facilities using the ML model; and providing a visualization interface including the map and the score of the one or more facilities responsive to the query.

Generally, program modules comprise routines, programs, components, data structures, etc., that perform particular tasks or implement particular abstract data types. Moreover, those skilled in the art will appreciate that the methods can be practiced with other computer system configurations, comprising single-processor or multiprocessor computer systems, minicomputers, mainframe computers, as well as personal computers, hand-held computing devices, microprocessor-based or programmable consumer electronics, and the like, each of which can be operatively coupled to one or more associated devices.

As used herein, a processing circuit includes one or more processors as well as other application specific circuits such as an application specific integrated circuit, digital logic circuit, state machine, programmable gate array or other circuit that processes input signals or data and that produces output signals or data in response thereto. It should be noted that while any functions and features described herein in association with the operation of a processor could likewise be performed by a processing circuit.

The illustrated embodiments of the embodiments herein can be also practiced in distributed computing environments where certain tasks are performed by remote processing devices that are linked through a communications network. In a distributed computing environment, program modules can be located in both local and remote memory storage devices.

Computing devices typically comprise a variety of media, which can comprise computer-readable storage media and/or communications media, which two terms are used herein differently from one another as follows. Computer-readable storage media can be any available storage media that can be accessed by the computer and comprises both volatile and nonvolatile media, removable and non-removable media. By way of example, and not limitation, computer-readable storage media can be implemented in connection with any method or technology for storage of information such as computer-readable instructions, program modules, structured data or unstructured data.

Computer-readable storage media can comprise, but are not limited to, random access memory (RAM), read only memory (ROM), electrically erasable programmable read only memory (EEPROM), flash memory or other memory technology, compact disk read only memory (CD-ROM), digital versatile disk (DVD) or other optical disk storage, magnetic cassettes, magnetic tape, magnetic disk storage or other magnetic storage devices or other tangible and/or non-transitory media which can be used to store desired information. In this regard, the terms “tangible” or “non-transitory” herein as applied to storage, memory or computer-readable media, are to be understood to exclude only propagating transitory signals per se as modifiers and do not relinquish rights to all standard storage, memory or computer-readable media that are not only propagating transitory signals per se.

Computer-readable storage media can be accessed by one or more local or remote computing devices, e.g., via access requests, queries or other data retrieval protocols, for a variety of operations with respect to the information stored by the medium.

Communications media typically embody computer-readable instructions, data structures, program modules or other structured or unstructured data in a data signal such as a modulated data signal, e.g., a carrier wave or other transport mechanism, and comprises any information delivery or transport media. The term “modulated data signal” or signals refers to a signal that has one or more of its characteristics set or changed in such a manner as to encode information in one or more signals. By way of example, and not limitation, communication media comprise wired media, such as a wired network or direct-wired connection, and wireless media such as acoustic, RF, infrared and other wireless media.

With reference again to FIG. 4, the example environment can comprise a computer 402, the computer 402 comprising a processing unit 404, a system memory 406 and a system bus 408. The system bus 408 couples system components including, but not limited to, the system memory 406 to the processing unit 404. The processing unit 404 can be any of various commercially available processors. Dual microprocessors and other multiprocessor architectures can also be employed as the processing unit 404.

The system bus 408 can be any of several types of bus structure that can further interconnect to a memory bus (with or without a memory controller), a peripheral bus, and a local bus using any of a variety of commercially available bus architectures. The system memory 406 comprises ROM 410 and RAM 412. A basic input/output system (BIOS) can be stored in a non-volatile memory such as ROM, erasable programmable read only memory (EPROM), EEPROM, which BIOS contains the basic routines that help to transfer information between elements within the computer 402, such as during startup. The RAM 412 can also comprise a high-speed RAM such as static RAM for caching data.

The computer 402 further comprises an internal hard disk drive (HDD) 414 (e.g., EIDE, SATA), which internal HDD 414 can also be configured for external use in a suitable chassis (not shown), a magnetic floppy disk drive (FDD) 416, (e.g., to read from or write to a removable diskette 418) and an optical disk drive 420, (e.g., reading a CD-ROM disk 422 or, to read from or write to other high capacity optical media such as the DVD). The HDD 414, magnetic FDD 416 and optical disk drive 420 can be connected to the system bus 408 by a hard disk drive interface 424, a magnetic disk drive interface 426 and an optical drive interface 428, respectively. The hard disk drive interface 424 for external drive implementations comprises at least one or both of Universal Serial Bus (USB) and Institute of Electrical and Electronics Engineers (IEEE) 1394 interface technologies. Other external drive connection technologies are within contemplation of the embodiments described herein.

The drives and their associated computer-readable storage media provide nonvolatile storage of data, data structures, computer-executable instructions, and so forth. For the computer 402, the drives and storage media accommodate the storage of any data in a suitable digital format. Although the description of computer-readable storage media above refers to a hard disk drive (HDD), a removable magnetic diskette, and a removable optical media such as a CD or DVD, it should be appreciated by those skilled in the art that other types of storage media which are readable by a computer, such as zip drives, magnetic cassettes, flash memory cards, cartridges, and the like, can also be used in the example operating environment, and further, that any such storage media can contain computer-executable instructions for performing the methods described herein.

A number of program modules can be stored in the drives and RAM 412, comprising an operating system 430, one or more application programs 432, other program modules 434 and program data 436. All or portions of the operating system, applications, modules, and/or data can also be cached in the RAM 412. The systems and methods described herein can be implemented utilizing various commercially available operating systems or combinations of operating systems.

A user can enter commands and information into the computer 402 through one or more wired/wireless input devices, e.g., a keyboard 438 and a pointing device, such as a mouse 440. Other input devices (not shown) can comprise a microphone, an infrared (IR) remote control, a joystick, a game pad, a stylus pen, touch screen or the like. These and other input devices are often connected to the processing unit 404 through an input device interface 442 that can be coupled to the system bus 408, but can be connected by other interfaces, such as a parallel port, an IEEE 1394 serial port, a game port, a universal serial bus (USB) port, an IR interface, etc.

A monitor 444 or other type of display device can be also connected to the system bus 408 via an interface, such as a video adapter 446. It will also be appreciated that in alternative embodiments, a monitor 444 can also be any display device (e.g., another computer having a display, a smart phone, a tablet computer, etc.) for receiving display information associated with computer 402 via any communication means, including via the Internet and cloud-based networks. In addition to the monitor 444, a computer typically comprises other peripheral output devices (not shown), such as speakers, printers, etc.

The computer 402 can operate in a networked environment using logical connections via wired and/or wireless communications to one or more remote computers, such as a remote computer(s) 448. The remote computer(s) 448 can be a workstation, a server computer, a router, a personal computer, portable computer, microprocessor-based entertainment appliance, a peer device or other common network node, and typically comprises many or all of the elements described relative to the computer 402, although, for purposes of brevity, only a remote memory/storage device 450 is illustrated. The logical connections depicted comprise wired/wireless connectivity to a local area network (LAN) 452 and/or larger networks, e.g., a wide area network (WAN) 454. Such LAN and WAN networking environments are commonplace in offices and companies, and facilitate enterprise-wide computer networks, such as intranets, all of which can connect to a global communications network, e.g., the Internet.

When used in a LAN networking environment, the computer 402 can be connected to the LAN 452 through a wired and/or wireless communication network interface or adapter 456. The adapter 456 can facilitate wired or wireless communication to the LAN 452, which can also comprise a wireless AP disposed thereon for communicating with the adapter 456.

When used in a WAN networking environment, the computer 402 can comprise a modem 458 or can be connected to a communications server on the WAN 454 or has other means for establishing communications over the WAN 454, such as by way of the Internet. The modem 458, which can be internal or external and a wired or wireless device, can be connected to the system bus 408 via the input device interface 442. In a networked environment, program modules depicted relative to the computer 402 or portions thereof, can be stored in the remote memory/storage device 450. It will be appreciated that the network connections shown are example and other means of establishing a communications link between the computers can be used.

The computer 402 can be operable to communicate with any wireless devices or entities operatively disposed in wireless communication, e.g., a printer, scanner, desktop and/or portable computer, portable data assistant, communications satellite, any piece of equipment or location associated with a wirelessly detectable tag (e.g., a kiosk, news stand, restroom), and telephone. This can comprise Wireless Fidelity (Wi-Fi) and BLUETOOTH® wireless technologies. Thus, the communication can be a predefined structure as with a conventional network or simply an ad hoc communication between at least two devices.

Wi-Fi can allow connection to the Internet from a couch at home, a bed in a hotel room or a conference room at work, without wires. Wi-Fi is a wireless technology similar to that used in a cell phone that enables such devices, e.g., computers, to send and receive data indoors and out; anywhere within the range of a base station. Wi-Fi networks use radio technologies called IEEE 802.11 (a, b, g, n, ac, ag, etc.) to provide secure, reliable, fast wireless connectivity. A Wi-Fi network can be used to connect computers to each other, to the Internet, and to wired networks (which can use IEEE 802.3 or Ethernet). Wi-Fi networks operate in the unlicensed 2.4 and 5 GHz radio bands for example or with products that contain both bands (dual band), so the networks can provide real-world performance similar to the basic 10BaseT wired Ethernet networks used in many offices.

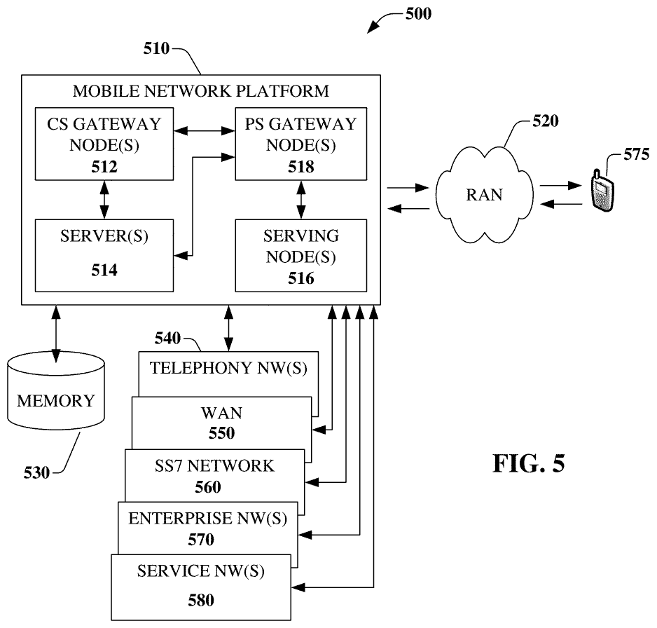

Turning now to FIG. 5, an embodiment 500 of a mobile network platform 510 is shown that is an example of network elements 150, 152, 154, 156, and/or VNEs 330, 332, 334, etc. For example, platform 510 can facilitate in whole or in part ingesting facilities infrastructure data; training a machine-learning (ML) model from the facilities infrastructure data; identifying one or more facilities provided in a region specified in a user query; generating a map of the one or more facilities using the ML model; and providing a visualization interface including the map and the score of the one or more facilities responsive to the query. In one or more embodiments, the mobile network platform 510 can generate and receive signals transmitted and received by base stations or access points such as base station or access point 122. Generally, mobile network platform 510 can comprise components, e.g., nodes, gateways, interfaces, servers, or disparate platforms, which facilitate both packet-switched (PS) (e.g., internet protocol (IP), frame relay, asynchronous transfer mode (ATM)) and circuit-switched (CS) traffic (e.g., voice and data), as well as control generation for networked wireless telecommunication. As a non-limiting example, mobile network platform 510 can be included in telecommunications carrier networks and can be considered carrier-side components as discussed elsewhere herein. Mobile network platform 510 comprises CS gateway node(s) 512 which can interface CS traffic received from legacy networks like telephony network(s) 540 (e.g., public switched telephone network (PSTN), or public land mobile network (PLMN)) or a signaling system #7 (SS7) network 560. CS gateway node(s) 512 can authorize and authenticate traffic (e.g., voice) arising from such networks. Additionally, CS gateway node(s) 512 can access mobility, or roaming, data generated through SS7 network 560; for instance, mobility data stored in a visited location register (VLR), which can reside in memory 530. Moreover, CS gateway node(s) 512 interfaces CS-based traffic and signaling and PS gateway node(s) 518. As an example, in a 3GPP UMTS network, CS gateway node(s) 512 can be realized at least in part in gateway GPRS support node(s) (GGSN). It should be appreciated that functionality and specific operation of CS gateway node(s) 512, PS gateway node(s) 518, and serving node(s) 516, is provided and dictated by radio technology(ies) utilized by mobile network platform 510 for telecommunication over a radio access network 520 with other devices, such as a radiotelephone 575.

In addition to receiving and processing CS-switched traffic and signaling, PS gateway node(s) 518 can authorize and authenticate PS-based data sessions with served mobile devices. Data sessions can comprise traffic, or content(s), exchanged with networks external to the mobile network platform 510, like wide area network(s) (WANs) 550, enterprise network(s) 570, and service network(s) 580, which can be embodied in local area network(s) (LANs), can also be interfaced with mobile network platform 510 through PS gateway node(s) 518. It is to be noted that WANs 550 and enterprise network(s) 570 can embody, at least in part, a service network(s) like IP multimedia subsystem (IMS). Based on radio technology layer(s) available in technology resource(s) or radio access network 520, PS gateway node(s) 518 can generate packet data protocol contexts when a data session is established; other data structures that facilitate routing of packetized data also can be generated. To that end, in an aspect, PS gateway node(s) 518 can comprise a tunnel interface (e.g., tunnel termination gateway (TTG) in 3GPP UMTS network(s) (not shown)) which can facilitate packetized communication with disparate wireless network(s), such as Wi-Fi networks.

In embodiment 500, mobile network platform 510 also comprises serving node(s) 516 that, based upon available radio technology layer(s) within technology resource(s) in the radio access network 520, convey the various packetized flows of data streams received through PS gateway node(s) 518. It is to be noted that for technology resource(s) that rely primarily on CS communication, server node(s) can deliver traffic without reliance on PS gateway node(s) 518; for example, server node(s) can embody at least in part a mobile switching center. As an example, in a 3GPP UMTS network, serving node(s) 516 can be embodied in serving GPRS support node(s) (SGSN).

For radio technologies that exploit packetized communication, server(s) 514 in mobile network platform 510 can execute numerous applications that can generate multiple disparate packetized data streams or flows, and manage (e.g., schedule, queue, format . . . ) such flows. Such application(s) can comprise add-on features to standard services (for example, provisioning, billing, customer support . . . ) provided by mobile network platform 510. Data streams (e.g., content(s) that are part of a voice call or data session) can be conveyed to PS gateway node(s) 518 for authorization/authentication and initiation of a data session, and to serving node(s) 516 for communication thereafter. In addition to application server, server(s) 514 can comprise utility server(s), a utility server can comprise a provisioning server, an operations and maintenance server, a security server that can implement at least in part a certificate authority and firewalls as well as other security mechanisms, and the like. In an aspect, security server(s) secure communication served through mobile network platform 510 to ensure network's operation and data integrity in addition to authorization and authentication procedures that CS gateway node(s) 512 and PS gateway node(s) 518 can enact. Moreover, provisioning server(s) can provision services from external network(s) like networks operated by a disparate service provider; for instance, WAN 550 or Global Positioning System (GPS) network(s) (not shown). Provisioning server(s) can also provision coverage through networks associated to mobile network platform 510 (e.g., deployed and operated by the same service provider), such as the distributed antennas networks shown in FIG. 1(s) that enhance wireless service coverage by providing more network coverage.

It is to be noted that server(s) 514 can comprise one or more processors configured to confer at least in part the functionality of mobile network platform 510. To that end, the one or more processors can execute code instructions stored in memory 530, for example. It should be appreciated that server(s) 514 can comprise a content manager, which operates in substantially the same manner as described hereinbefore.

In example embodiment 500, memory 530 can store information related to operation of mobile network platform 510. Other operational information can comprise provisioning information of mobile devices served through mobile network platform 510, subscriber databases; application intelligence, pricing schemes, e.g., promotional rates, flat-rate programs, couponing campaigns; technical specification(s) consistent with telecommunication protocols for operation of disparate radio, or wireless, technology layers; and so forth. Memory 530 can also store information from at least one of telephony network(s) 540, WAN 550, SS7 network 560, or enterprise network(s) 570. In an aspect, memory 530 can be, for example, accessed as part of a data store component or as a remotely connected memory store.

In order to provide a context for the various aspects of the disclosed subject matter, FIG. 5, and the following discussion, are intended to provide a brief, general description of a suitable environment in which the various aspects of the disclosed subject matter can be implemented. While the subject matter has been described above in the general context of computer-executable instructions of a computer program that runs on a computer and/or computers, those skilled in the art will recognize that the disclosed subject matter also can be implemented in combination with other program modules. Generally, program modules comprise routines, programs, components, data structures, etc. that perform particular tasks and/or implement particular abstract data types.

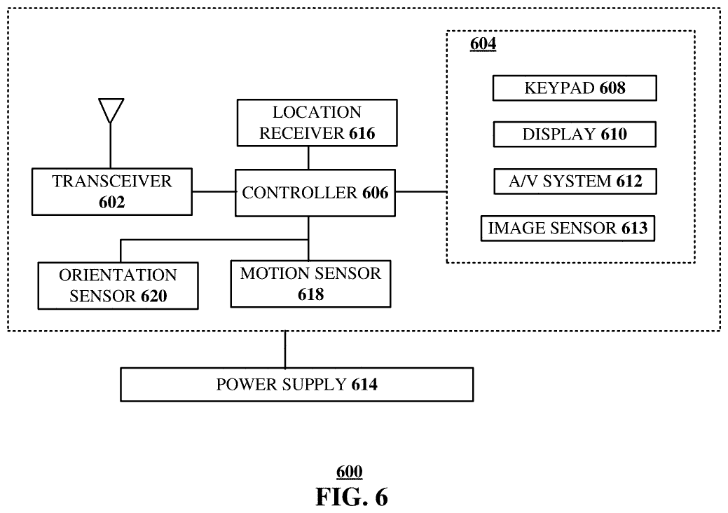

Turning now to FIG. 6, an illustrative embodiment of a communication device 600 is shown. The communication device 600 can serve as an illustrative embodiment of devices such as data terminals 114, mobile devices 124, a vehicle 126, display devices 144 or other client devices for communication via either communications network 125. For example, computing device 600 can facilitate in whole or in part ingesting facilities infrastructure data; training a machine-learning (ML) model from the facilities infrastructure data; identifying one or more facilities provided in a region specified in a user query; generating a map of the one or more facilities using the ML model; and providing a visualization interface including the map and the score of the one or more facilities responsive to the query.

The communication device 600 can comprise a wireline and/or wireless transceiver 602 (herein transceiver 602), a user interface (UI) 604, a power supply 614, a location receiver 616, a motion sensor 618, an orientation sensor 620, and a controller 606 for managing operations thereof. The transceiver 602 can support short-range or long-range wireless access technologies such as Bluetooth®, ZigBee®, Wi-Fi, DECT, or cellular communication technologies, just to mention a few (Bluetooth® and ZigBee® are trademarks registered by the Bluetooth® Special Interest Group and the ZigBee® Alliance, respectively). Cellular technologies can include, for example, CDMA-1X, UMTS/HSDPA, GSM/GPRS, TDMA/EDGE, EV/DO, WiMAX, SDR, LTE, as well as other next generation wireless communication technologies as they arise. The transceiver 602 can also be adapted to support circuit-switched wireline access technologies (such as PSTN), packet-switched wireline access technologies (such as TCP/IP, VoIP, etc.), and combinations thereof.

The UI 604 can include a depressible or touch-sensitive keypad 608 with a navigation mechanism such as a roller ball, a joystick, a mouse, or a navigation disk for manipulating operations of the communication device 600. The keypad 608 can be an integral part of a housing assembly of the communication device 600 or an independent device operably coupled thereto by a tethered wireline interface (such as a USB cable) or a wireless interface supporting for example Bluetooth®. The keypad 608 can represent a numeric keypad commonly used by phones, and/or a QWERTY keypad with alphanumeric keys. The UI 604 can further include a display 610 such as monochrome or color LCD (Liquid Crystal Display), OLED (Organic Light Emitting Diode) or other suitable display technology for conveying images to an end user of the communication device 600. In an embodiment where the display 610 is touch-sensitive, a portion or all of the keypad 608 can be presented by way of the display 610 with navigation features.

The display 610 can use touch screen technology to also serve as a user interface for detecting user input. As a touch screen display, the communication device 600 can be adapted to present a user interface having graphical user interface (GUI) elements that can be selected by a user with a touch of a finger. The display 610 can be equipped with capacitive, resistive or other forms of sensing technology to detect how much surface area of a user's finger has been placed on a portion of the touch screen display. This sensing information can be used to control the manipulation of the GUI elements or other functions of the user interface. The display 610 can be an integral part of the housing assembly of the communication device 600 or an independent device communicatively coupled thereto by a tethered wireline interface (such as a cable) or a wireless interface.

The UI 604 can also include an audio system 612 that utilizes audio technology for conveying low volume audio (such as audio heard in proximity of a human ear) and high-volume audio (such as speakerphone for hands free operation). The audio system 612 can further include a microphone for receiving audible signals of an end user. The audio system 612 can also be used for voice recognition applications. The UI 604 can further include an image sensor 613 such as a charged coupled device (CCD) camera for capturing still or moving images.

The power supply 614 can utilize common power management technologies such as replaceable and rechargeable batteries, supply regulation technologies, and/or charging system technologies for supplying energy to the components of the communication device 600 to facilitate long-range or short-range portable communications. Alternatively, or in combination, the charging system can utilize external power sources such as DC power supplied over a physical interface such as a USB port or other suitable tethering technologies.

The location receiver 616 can utilize location technology such as a global positioning system (GPS) receiver capable of assisted GPS for identifying a location of the communication device 600 based on signals generated by a constellation of GPS satellites, which can be used for facilitating location services such as navigation. The motion sensor 618 can utilize motion sensing technology such as an accelerometer, a gyroscope, or other suitable motion sensing technology to detect motion of the communication device 600 in three-dimensional space. The orientation sensor 620 can utilize orientation sensing technology such as a magnetometer to detect the orientation of the communication device 600 (north, south, west, and east, as well as combined orientations in degrees, minutes, or other suitable orientation metrics).

The communication device 600 can use the transceiver 602 to also determine a proximity to a cellular, Wi-Fi, Bluetooth®, or other wireless access points by sensing techniques such as utilizing a received signal strength indicator (RSSI) and/or signal time of arrival (TOA) or time of flight (TOF) measurements. The controller 606 can utilize computing technologies such as a microprocessor, a digital signal processor (DSP), programmable gate arrays, application specific integrated circuits, and/or a video processor with associated storage memory such as Flash, ROM, RAM, SRAM, DRAM or other storage technologies for executing computer instructions, controlling, and processing data supplied by the aforementioned components of the communication device 600.

Other components not shown in FIG. 6 can be used in one or more embodiments of the subject disclosure. For instance, the communication device 600 can include a slot for adding or removing an identity module such as a Subscriber Identity Module (SIM) card or Universal Integrated Circuit Card (UICC). SIM or UICC cards can be used for identifying subscriber services, executing programs, storing subscriber data, and so on.

The terms “first,” “second,” “third,” and so forth, as used in the claims, unless otherwise clear by context, is for clarity only and does not otherwise indicate or imply any order in time. For instance, “a first determination,” “a second determination,” and “a third determination,” does not indicate or imply that the first determination is to be made before the second determination, or vice versa, etc.

In the subject specification, terms such as “store,” “storage,” “data store,” data storage,” “database,” and substantially any other information storage component relevant to operation and functionality of a component, refer to “memory components,” or entities embodied in a “memory” or components comprising the memory. It will be appreciated that the memory components described herein can be either volatile memory or nonvolatile memory, or can comprise both volatile and nonvolatile memory, by way of illustration, and not limitation, volatile memory, non-volatile memory, disk storage, and memory storage. Further, nonvolatile memory can be included in read only memory (ROM), programmable ROM (PROM), electrically programmable ROM (EPROM), electrically erasable ROM (EEPROM), or flash memory. Volatile memory can comprise random access memory (RAM), which acts as external cache memory. By way of illustration and not limitation, RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), and direct Rambus RAM (DRRAM). Additionally, the disclosed memory components of systems or methods herein are intended to comprise, without being limited to comprising, these and any other suitable types of memory.

Moreover, it will be noted that the disclosed subject matter can be practiced with other computer system configurations, comprising single-processor or multiprocessor computer systems, mini-computing devices, mainframe computers, as well as personal computers, hand-held computing devices (e.g., PDA, phone, smartphone, watch, tablet computers, netbook computers, etc.), microprocessor-based or programmable consumer or industrial electronics, and the like. The illustrated aspects can also be practiced in distributed computing environments where tasks are performed by remote processing devices that are linked through a communications network; however, some if not all aspects of the subject disclosure can be practiced on stand-alone computers. In a distributed computing environment, program modules can be located in both local and remote memory storage devices.

In one or more embodiments, information regarding use of services can be generated including services being accessed, media consumption history, user preferences, and so forth. This information can be obtained by various methods including user input, detecting types of communications (e.g., video content vs. audio content), analysis of content streams, sampling, and so forth. The generating, obtaining and/or monitoring of this information can be responsive to an authorization provided by the user. In one or more embodiments, an analysis of data can be subject to authorization from user(s) associated with the data, such as an opt-in, an opt-out, acknowledgement requirements, notifications, selective authorization based on types of data, and so forth.

Some of the embodiments described herein can also employ artificial intelligence (AI) to facilitate automating one or more features described herein. The embodiments (e.g., in connection with automatically identifying acquired cell sites that provide a maximum value/benefit after addition to an existing communication network) can employ various AI-based schemes for conducting various embodiments thereof. Moreover, the classifier can be employed to determine a ranking or priority of each cell site of the acquired network. A classifier is a function that maps an input attribute vector, x=(x₁, x₂, x₃, x₄ . . . xₙ), to a confidence that the input belongs to a class, that is, f(x)=confidence (class). Such classification can employ a probabilistic and/or statistical-based analysis (e.g., factoring into the analysis utilities and costs) to determine or infer an action that a user desires to be automatically performed. A support vector machine (SVM) is an example of a classifier that can be employed. The SVM operates by finding a hypersurface in the space of possible inputs, which the hypersurface attempts to split the triggering criteria from the non-triggering events. Intuitively, this makes the classification correct for testing data that is near, but not identical to training data. Other directed and undirected model classification approaches comprise, e.g., naïve Bayes, Bayesian networks, decision trees, neural networks, fuzzy logic models, and probabilistic classification models providing different patterns of independence can be employed. Classification as used herein also is inclusive of statistical regression that is utilized to develop models of priority.

As will be readily appreciated, one or more of the embodiments can employ classifiers that are explicitly trained (e.g., via a generic training data) as well as implicitly trained (e.g., via observing UE behavior, operator preferences, historical information, receiving extrinsic information). For example, SVMs can be configured via a learning or training phase within a classifier constructor and feature selection module. Thus, the classifier(s) can be used to automatically learn and perform a number of functions, including but not limited to determining according to predetermined criteria which of the acquired cell sites will benefit a maximum number of subscribers and/or which of the acquired cell sites will add minimum value to the existing communication network coverage, etc.

As used in some contexts in this application, in some embodiments, the terms “component,” “system” and the like are intended to refer to, or comprise, a computer-related entity or an entity related to an operational apparatus with one or more specific functionalities, wherein the entity can be either hardware, a combination of hardware and software, software, or software in execution. As an example, a component may be, but is not limited to being, a process running on a processor, a processor, an object, an executable, a thread of execution, computer-executable instructions, a program, and/or a computer. By way of illustration and not limitation, both an application running on a server and the server can be a component. One or more components may reside within a process and/or thread of execution and a component may be localized on one computer and/or distributed between two or more computers. In addition, these components can execute from various computer readable media having various data structures stored thereon. The components may communicate via local and/or remote processes such as in accordance with a signal having one or more data packets (e.g., data from one component interacting with another component in a local system, distributed system, and/or across a network such as the Internet with other systems via the signal). As another example, a component can be an apparatus with specific functionality provided by mechanical parts operated by electric or electronic circuitry, which is operated by a software or firmware application executed by a processor, wherein the processor can be internal or external to the apparatus and executes at least a part of the software or firmware application. As yet another example, a component can be an apparatus that provides specific functionality through electronic components without mechanical parts, the electronic components can comprise a processor therein to execute software or firmware that confers at least in part the functionality of the electronic components. While various components have been illustrated as separate components, it will be appreciated that multiple components can be implemented as a single component, or a single component can be implemented as multiple components, without departing from example embodiments.

Further, the various embodiments can be implemented as a method, apparatus or article of manufacture using standard programming and/or engineering techniques to produce software, firmware, hardware or any combination thereof to control a computer to implement the disclosed subject matter. The term “article of manufacture” as used herein is intended to encompass a computer program accessible from any computer-readable device or computer-readable storage/communications media. For example, computer readable storage media can include, but are not limited to, magnetic storage devices (e.g., hard disk, floppy disk, magnetic strips), optical disks (e.g., compact disk (CD), digital versatile disk (DVD)), smart cards, and flash memory devices (e.g., card, stick, key drive). Of course, those skilled in the art will recognize many modifications can be made to this configuration without departing from the scope or spirit of the various embodiments.

In addition, the words “example” and “exemplary” are used herein to mean serving as an instance or illustration. Any embodiment or design described herein as “example” or “exemplary” is not necessarily to be construed as preferred or advantageous over other embodiments or designs. Rather, use of the word example or exemplary is intended to present concepts in a concrete fashion. As used in this application, the term “or” is intended to mean an inclusive “or” rather than an exclusive “or.” That is, unless specified otherwise or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

Moreover, terms such as “user equipment,” “mobile station,” “mobile,” subscriber station,” “access terminal,” “terminal,” “handset,” “mobile device” (and/or terms representing similar terminology) can refer to a wireless device utilized by a subscriber or user of a wireless communication service to receive or convey data, control, voice, video, sound, gaming or substantially any data-stream or signaling-stream. The foregoing terms are utilized interchangeably herein and with reference to the related drawings.

Furthermore, the terms “user,” “subscriber,” “customer,” “consumer” and the like are employed interchangeably throughout, unless context warrants particular distinctions among the terms. It should be appreciated that such terms can refer to human entities or automated components supported through artificial intelligence (e.g., a capacity to make inference based, at least, on complex mathematical formalisms), which can provide simulated vision, sound recognition and so forth.

As employed herein, the term “processor” can refer to substantially any computing processing unit or device comprising, but not limited to comprising, single-core processors; single-processors with software multithread execution capability; multi-core processors; multi-core processors with software multithread execution capability; multi-core processors with hardware multithread technology; parallel platforms; and parallel platforms with distributed shared memory. Additionally, a processor can refer to an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components or any combination thereof designed to perform the functions described herein. Processors can exploit nano-scale architectures such as, but not limited to, molecular and quantum-dot based transistors, switches and gates, in order to optimize space usage or enhance performance of user equipment. A processor can also be implemented as a combination of computing processing units.

As used herein, terms such as “data storage,” data storage,” “database,” and substantially any other information storage component relevant to operation and functionality of a component, refer to “memory components,” or entities embodied in a “memory” or components comprising the memory. It will be appreciated that the memory components or computer-readable storage media, described herein can be either volatile memory or nonvolatile memory or can include both volatile and nonvolatile memory.

What has been described above includes mere examples of various embodiments. It is, of course, not possible to describe every conceivable combination of components or methodologies for purposes of describing these examples, but one of ordinary skill in the art can recognize that many further combinations and permutations of the present embodiments are possible. Accordingly, the embodiments disclosed and/or claimed herein are intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

In addition, a flow diagram may include a “start” and/or “continue” indication. The “start” and “continue” indications reflect that the steps presented can optionally be incorporated in or otherwise used in conjunction with other routines. In this context, “start” indicates the beginning of the first step presented and may be preceded by other activities not specifically shown. Further, the “continue” indication reflects that the steps presented may be performed multiple times and/or may be succeeded by other activities not specifically shown. Further, while a flow diagram indicates a particular ordering of steps, other orderings are likewise possible provided that the principles of causality are maintained.

As may also be used herein, the term(s) “operably coupled to,” “coupled to,” and/or “coupling” includes direct coupling between items and/or indirect coupling between items via one or more intervening items. Such items and intervening items include, but are not limited to, junctions, communication paths, components, circuit elements, circuits, functional blocks, and/or devices. As an example of indirect coupling, a signal conveyed from a first item to a second item may be modified by one or more intervening items by modifying the form, nature or format of information in a signal, while one or more elements of the information in the signal are nevertheless conveyed in a manner than can be recognized by the second item. In a further example of indirect coupling, an action in a first item can cause a reaction on the second item, as a result of actions and/or reactions in one or more intervening items.

Although specific embodiments have been illustrated and described herein, it should be appreciated that any arrangement which achieves the same or similar purpose may be substituted for the embodiments described or shown by the subject disclosure. The subject disclosure is intended to cover any and all adaptations or variations of various embodiments. Combinations of the above embodiments, and other embodiments not specifically described herein, can be used in the subject disclosure. For instance, one or more features from one or more embodiments can be combined with one or more features of one or more other embodiments. In one or more embodiments, features that are positively recited can also be negatively recited and excluded from the embodiment with or without replacement by another structural and/or functional feature. The steps or functions described with respect to the embodiments of the subject disclosure can be performed in any order. The steps or functions described with respect to the embodiments of the subject disclosure can be performed alone or in combination with other steps or functions of the subject disclosure, as well as from other embodiments or from other steps that have not been described in the subject disclosure. Further, more than or less than all of the features described with respect to an embodiment can also be utilized.

What is claimed is:

1. A device, comprising:
a processing system including a processor; and
a memory that stores executable instructions that, when executed by the processing system, facilitate performance of operations, the operations comprising:
ingesting facilities infrastructure data for more than one facility;
training a machine-learning (ML) model from the facilities infrastructure data, wherein the ML model infers features absent in the facilities infrastructure data and yields a score of a facility described by the facilities infrastructure data;
receiving a query for a region from a user;
identifying one or more facilities provided in the region;
generating a map of the one or more facilities using the ML model; and
providing a visualization interface to the user including the map and the score of the one or more facilities responsive to the query.

2. The device of claim 1, wherein the ML model infers features absent in the facilities infrastructure data from additional textual, geographic and visual information.

3. The device of claim 1, wherein the facilities infrastructure data comprises several types of facilities data, wherein the types of the facilities data comprise power distribution, telecom, cellular, cable, water, sewer or a combination thereof.

4. The device of claim 1, wherein the facilities infrastructure data includes a location of facilities.

5. The device of claim 1, wherein the facilities infrastructure data includes a quality of services provided by the one or more facilities.

6. The device of claim 1, wherein the facilities infrastructure data includes installation data indicating a time of installation, last service, material type and location.

7. The device of claim 1, wherein the facilities infrastructure data includes service level data comprising throughput of service provided by the one or more facilities and error rate.

8. The device of claim 1, wherein the operations further comprise detecting gaps in coverage of facilities in the region.

9. The device of claim 1, wherein the score is presented as a heat map.

10. The device of claim 1, wherein the visualization interface comprises augmented reality.

11. The device of claim 1, wherein the visualization interface comprises a two-dimensional overlay map.

12. The device of claim 1, wherein the visualization interface comprises a virtual anchor and wherein the operations further comprise receiving additional facilities infrastructure data provided by the user.

13. The device of claim 1, wherein the visualization interface provides repeating and time-delayed responses to a user query.

14. A non-transitory, machine-readable medium, comprising executable instructions that, when executed by a processing system including a processor, facilitate performance of operations, the operations comprising:
receiving facilities infrastructure data for more than one facility;
training a machine-learning (ML) model from the facilities infrastructure data, wherein the ML model infers features absent in the facilities infrastructure data and yields a score of a facility described by the facilities infrastructure data;
receiving a query for a region from a user;
identifying one or more facilities provided in the region;
generating a map of the one or more facilities using the ML model; and
providing a visualization interface to the user including the map and the score of the one or more facilities responsive to the query.

15. The non-transitory, machine-readable medium of claim 14, wherein the ML model infers features absent in the facilities infrastructure data from additional textual, geographic and visual information.

16. The non-transitory, machine-readable medium of claim 14, wherein the facilities infrastructure data comprises several types of facilities data including power distribution, telecom, cellular, cable, water and sewer.

17. The non-transitory, machine-readable medium of claim 14, wherein the facilities infrastructure data includes a location of facilities, a quality of services provided by the facilities, and installation data indicating a time of installation, last service, and material type.

18. The non-transitory, machine-readable medium of claim 14, wherein the processing system comprises a plurality of processors operating in a distributed computing environment.

19. A method, comprising:
creating, by a processing system including a processor, a machine-learning (ML) model from facilities infrastructure data, wherein the ML model infers features absent in the facilities infrastructure data and yields a score of a facility described by the facilities infrastructure data;
receiving, by the processing system, a query for a region from a user;
identifying, by the processing system, one or more facilities provided in the region;
generating, by the processing system, a map of the one or more facilities using the ML model; and
providing, by the processing system, a visualization interface to the user including the map and the score of the one or more facilities responsive to the query.

20. The method of claim 19, wherein the visualization interface comprises a virtual anchor and wherein the method further comprises receiving additional facilities infrastructure data provided by the user.
